(19) United States
(12) Patent Application Publication
(10) Pub. No.: US 2015/0229281 A1
(43) Pub. Date: Aug. 13, 2015

(54) BANDWIDTH IMPROVEMENT FOR RECEIVERS

(71) Applicant: Fujitsu Limited, Kawasaki-shi (JP)

(72) Inventor: Jian Hong JIANG, Los Altos, CA (US)

(73) Assignee: Fujitsu Limited, Kawasaki-shi (JP)

(21) Appl. No.: 14/179,605

(22) Filed: Feb. 13, 2014

(51) Int. Cl. H03F 1/42; H04B 10/69; H03F 3/08

(52) U.S. Cl. CPC H03F 1/42; H03F 3/08; H04B 10/69; H03F 2200/117; H03F 2200/129; H03F 2200/147

(57) ABSTRACT

A receiver circuit is provided. The receiver circuit may include an amplifying circuit. The amplifying circuit may include an input node, an output node, and a feedback loop coupled between the input node and the output node. The feedback loop may include a first inductor. The amplifying circuit may be configured to receive a current signal on the input node and to output a voltage signal based on the current signal on the output node. The receiver circuit may also include a second inductor with a first node coupled to the input node of the amplifying circuit.

### FIELD

The embodiments discussed herein are related to bandwidth improvement for receivers.

### BACKGROUND

When receiving high-speed signals, a receiver's input may suffer from impedance mismatch with a transmission line that supplies the high-speed signals to the receiver's input. The impedance mismatch may be due to differences in an impedance of the transmission line and an impedance of the receiver's input. The impedance mismatch may cause one or more signal reflections of the high-speed signals that may result in signal loss and may distort incoming data. The result of signal reflections on signals may be quantified as a return loss of the signals. The amount of return loss in receivers may vary based on the transmission line, the receiver design, and the speeds of the signals being transmitted.

A receiver may also amplify high-speed signals. The ability of a receiver to amplify a high-speed signal may be related to a bandwidth of the receiver. Larger bandwidths of a receiver may allow for higher-speed signals to be properly amplified by the receiver.

The subject matter claimed herein is not limited to embodiments that solve any disadvantages or that operate only in environments such as those described above. Rather, this background is only provided to illustrate one example technology area where some embodiments described herein may be practiced.

### SUMMARY

According to an aspect of an embodiment, a receiver circuit is provided. The receiver circuit may include an amplifying circuit. The amplifying circuit may include an input node, an output node, and a feedback loop coupled between the input node and the output node. The feedback loop may include a first inductor. The amplifying circuit may be configured to receive a current signal on the input node and to output a voltage signal based on the current signal on the output node. The receiver circuit may also include a second inductor with a first node coupled to the input node of the amplifying circuit.

The object and advantages of the embodiments will be realized and achieved at least by the elements, features, and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

Example embodiments will be described and explained with additional specificity and detail through the use of the accompanying drawings in which:

FIG. 1 is a circuit diagram of an example receiver circuit with reduced signal loss;

FIGS. 2A and 2B are graphs that illustrate various characteristics of the example receiver circuit of FIG. 1;

FIG. 3 is a circuit diagram of an optical receiver that includes an example transimpedance amplifying circuit with reduced signal loss;

FIG. 4 is a circuit diagram of another example optical receiver with an improved return loss; and

FIG. 5 is a flowchart of an example method of reducing return loss in a receiver circuit.

### DESCRIPTION OF EMBODIMENTS

According to an aspect of an embodiment, an optical receiver is disclosed that includes a transimpedance amplifier and that has a reduced return loss over an extended bandwidth. The reduced return loss over an extended bandwidth of the optical receiver may be a result of the optical receiver including an inductor that is coupled to an input node of transimpedance amplifier.

Embodiments of the present invention will be explained with reference to the accompanying drawings.

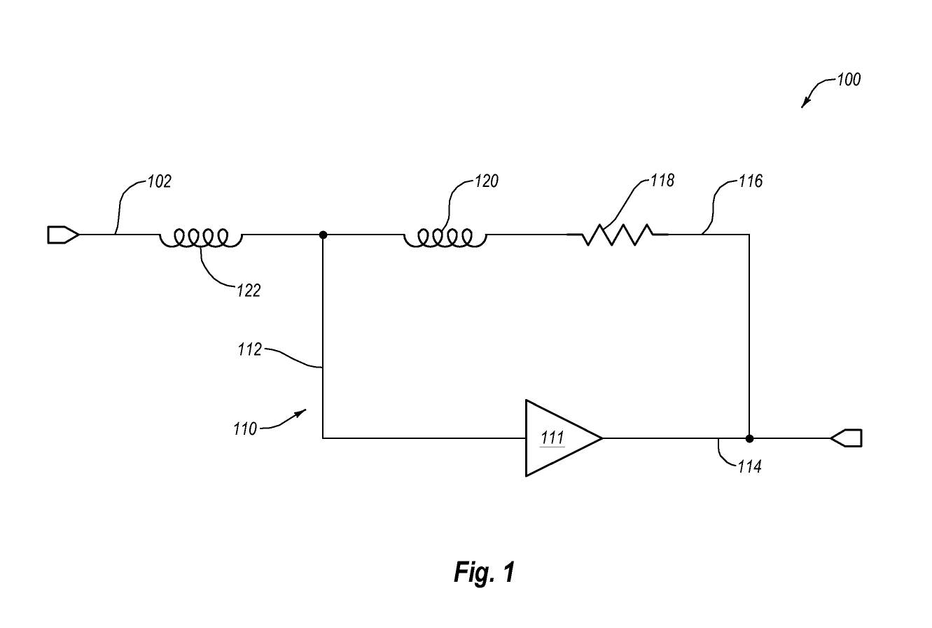

FIG. 1 is a circuit diagram of an example receiver circuit 100 with reduced signal loss, arranged in accordance with at least one embodiment described herein. The receiver circuit 100 may include an amplifying circuit 110, which includes a first inductor 120, and a second inductor 122.

The amplifying circuit 110 may include an amplifier 111, an input node 112, an output node 114, and a feedback loop 116 that couples the input node 112 to the output node 114. The feedback loop 116 may include a resistance 118, such as one or more resistors or other components that offer resistance, such as a body of a transistor, and the first inductor 120. The first inductor 120 may be coupled to the input node 112, the resistance 118 may be coupled to the output node 114, and the first inductor 120 and the resistance 118 may be coupled together.

The amplifying circuit 110 may be configured as a transimpedance amplifying circuit. In these and other embodiments, the amplifying circuit 110 may be configured to receive a current signal at the input node 112 and to output a voltage signal on the output node 114 that is based on the current signal and a gain or amplification factor of the amplifying circuit 110. The amplifying circuit 110 may convert the current signal at the input node 112 to the voltage signal at the output node 114 using the resistance 118 in the feedback loop 116. In short, a current related to the current signal may pass through the resistance 118 to generate the voltage signal at the output node 114. In some embodiments, a gain of the amplifying circuit 110 may be positive, negative, or zero.

A first side of the second inductor 122 may be coupled to the input node 112. A second side of the second inductor 122 may be configured coupled to an input node 102 of the receiver circuit 100 and configured to receive a current signal that may be provided to the amplifying circuit 110.

In some embodiments, the inductances of the second inductor 122 and the first inductor 120 may be related based on the gain of the amplifying circuit 110. For example, in some embodiments, the inductance of the second inductor 122 may be approximately equal to the inductance of the first inductor 120 divided by the gain of amplifying circuit 110. Configuring the inductance of the second inductor 122 to be approximately equal to the inductance of the first inductor 120 divided by the gain of amplifying circuit 110 may allow more inductive coupling between the first and second inductors 120 and 122. Increased inductive coupling between the first and second inductors 120 and 122 may increase an effective inductance of each of the first and second inductors 120 and 122 during operation, allowing for the actual inductance of each of the first and second inductors 120 and 122 to be reduced. Reducing the actual inductance of each of the first and second inductors 120 and 122 may allow for the physical size of the first and second inductors 120 and 122 to be reduced.

In some embodiments, the first and second inductors 120 and 122 may be selected to have resonant frequencies that are higher than a highest frequency of a current signal received at the input node 102 of the receiver circuit 100. The first and second inductors 120 and 122 having resonant frequencies higher than a highest frequency of a current signal provided to the receiver circuit 100 may reduce an ability of the first and/or second inductors 120 and 122 to resonate and to introduce abnormalities in the voltage signal output by the amplifying circuit 110. In some embodiments, each of or only one of the first and second inductors 120 and 122 may be monolithic inductors.

Combining the amplifying circuit 110 and the second inductor 122 as described may result in benefits for the receiver circuit 100. For example, the second inductor 122 may help to reduce return loss of the receiver circuit 100 over a broader bandwidth of frequencies. Return loss may be a result of impedance mismatches between coupled components. For example, an impedance mismatch may occur between a trace (not illustrated) and the input node 102 of the receiver circuit 100. An impedance mismatch may cause one or more signal reflections of a signal traveling between the components. The signal reflections may distort the signal and/or result in signal loss. The result of signal reflections on signals may be quantified as a return loss of the signals. Reducing the return loss of the receiver circuit 100 over a broader bandwidth of frequencies may be referred to herein as extending the return loss bandwidth of the receiver circuit 100. Extending the return loss bandwidth of the receiver circuit 100 may result in a cleaner, e.g., less distorted, signal being provided to the amplifying circuit 110 and thus a better output signal by the amplifying circuit 110 on the output node 114 over a larger bandwidth.

To extend the return loss bandwidth of the receiver circuit 100, the input impedance of the receiver circuit 100 at the input node 102 may be maintained at a specified value over a larger range of frequencies (bandwidth). Maintaining the input impedance of the receiver circuit 100 at the input node 102 at the specified value over a larger bandwidth may allow the input impedance of the receiver circuit 100 to approximate an impedance of a component, such as a trace, coupled to the receiver circuit 100 over a larger bandwidth. Approximating an impedance of a component coupled to the receiver circuit 100 may reduce reflections of signals passing from the component to the receiver circuit 100 and thus may reduce a return loss of the receiver circuit 100.

For example, in some circumstances, the input impedance of the receiver circuit 100 without the second inductor 122 may decrease at higher frequencies, resulting in an impedance mismatch between the input impedance of the receiver circuit 100 and a trace coupled to the receiver circuit 100. With the second inductor 122 coupled between the input node 112 of the amplifying circuit 110 and the input node 102 of the receiver circuit, however, at higher frequencies, the input impedance of the receiver circuit 100 may increase thereby compensating for other decreases in the input impedance of the receiver circuit 100. As a result of the impedance of the second inductor 122 compensating for the decrease in the input impedance of the receiver circuit 100, the input impedance of the receiver circuit 100 may maintain more stable at higher frequencies and thereby extend the return loss bandwidth of the receiver circuit 100 and allow the receiver circuit 100 to provide a cleaner signal over a larger bandwidth.

Benefits may also be derived from the first inductor 120 as well. In particular, the amplifying circuit 110, including the first inductor 120 as described, may help to extend a transimpedance bandwidth of the amplifying circuit 110. The transimpedance bandwidth of the amplifying circuit 110 may relate to and/or include the frequencies at which changes in the current signal at the input node 112 results in similar changes in the output voltage signal at the output node 114. At higher frequencies, the impedance of the feedback loop 116 without the first inductor 120 may reduce, resulting in a change in current in the feedback loop 116 not generating a similar change in the voltage in the feedback loop 116 and thus not resulting in a change in the output voltage signal. The impedance of the first inductor 120, however, increases at higher frequencies to help offset reduction of the impedance of the feedback loop 116. By maintaining a similar impedance in the feedback loop 116 at higher frequencies, the amplifying circuit 110 may operate to convert the current signal to the voltage signal in a similar manner at the higher frequencies as the amplifying circuit 110 converts the current signal at lower frequencies, thereby extending the transimpedance bandwidth of the amplifying circuit 110.

Modifications, additions, or omissions may be made to the receiver circuit 100 without departing from the scope of the present disclosure. For example, in some embodiments, one or more active components, such as transistors and diodes, or passive components, such as resistors, capacitors, and inductors, may be part of the receiver circuit 100. For example, one or more diodes may be coupled to the input node 112 for electrostatic discharge protection.

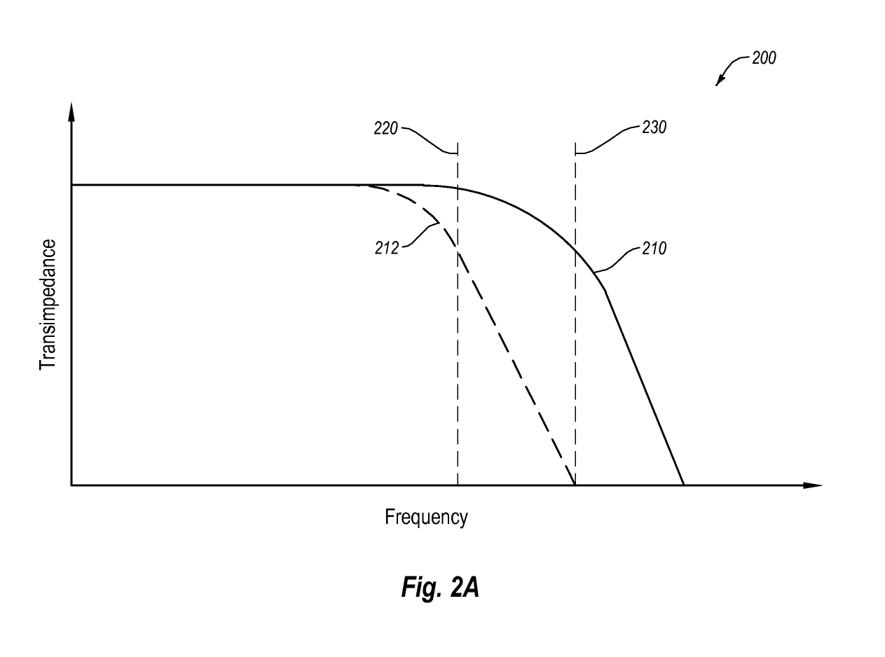

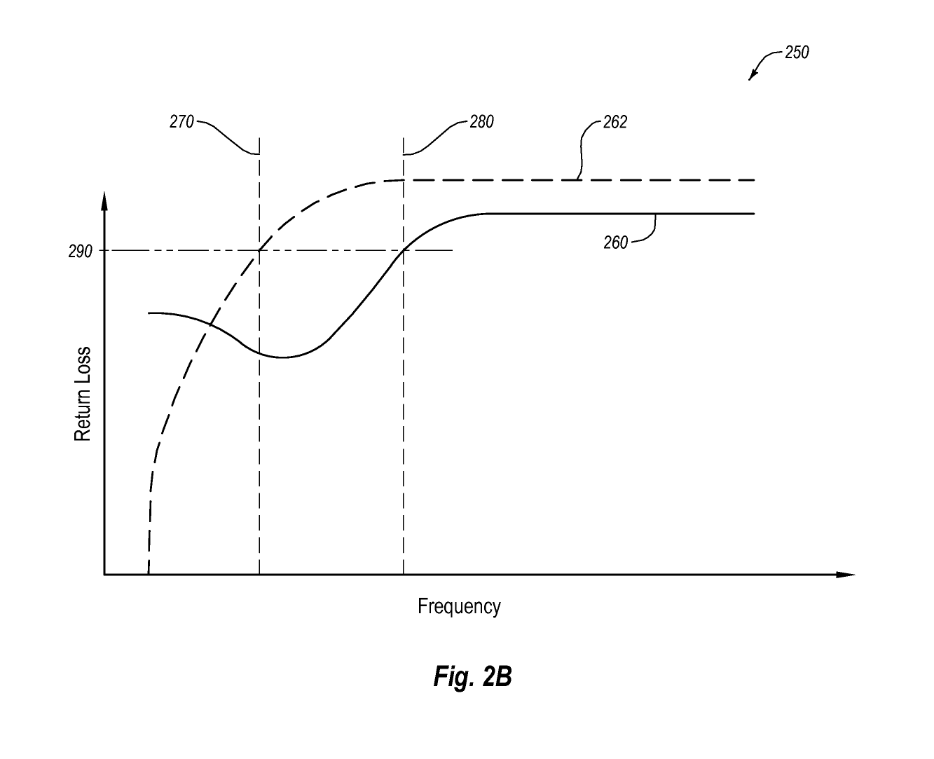

FIG. 2A is a graph 200 that illustrates a characteristic of the receiver circuit 100 of FIG. 1, in accordance with at least one embodiment described herein. The graph 200 has an x-axis that represents a frequency of a signal received by the receiver circuit 100. The graph 200 has a y-axis that represents a magnitude of the transimpedance of the amplifying circuit 110. The line 210 represents a magnitude of the transimpedance of the amplifying circuit 110 with respect to frequency when the receiver circuit 100 includes the first inductor 120. The line 212 represents a magnitude of the transimpedance of the amplifying circuit 110 with respect to frequency when the receiver circuit 100 does not include the first inductor 120.

For example, at a first frequency 220, if the receiver circuit 100 does not include the first inductor 120, then the transimpedance of the amplifying circuit 110 may decrease below a minimum acceptable value as illustrated by line 212. When the receiver circuit 100 includes the first inductor 120, then the bandwidth of the transimpedance of the amplifying circuit 110 may be extended as illustrated by line 210. In particular, as illustrated in FIG. 2A, the bandwidth of the transimpedance may be extended to a second frequency 230 before the transimpedance of the amplifying circuit 110 decreases below the minimum acceptable value.

FIG. 2B is a graph 250 that illustrates a characteristic of the receiver circuit 100 of FIG. 1, in accordance with at least one embodiment described herein. The graph 250 has an x-axis that represents a frequency of a signal received by the receiver circuit 100. The graph 250 has a y-axis that represents a magnitude of the return loss of the receiver circuit 100. The line 260 represents a magnitude of the return loss of the receiver circuit 100 with respect to frequency when the receiver circuit 100 includes the second inductor 122. The line 262 represents a magnitude of the return loss of the receiver circuit 100 with respect to frequency when the receiver circuit 100 does not include the second inductor 122.

For example, at a first frequency 270, if the receiver circuit 100 does not include the second inductor 122, then return loss of the receiver circuit 100 may reach and then exceed an undesirable level 290 as illustrated by line 262. When the receiver circuit 100 includes the second inductor 122, the bandwidth of the return loss of the receiver circuit 100 may be extended as illustrated by line 260. In particular, as illustrated in FIG. 2B, the bandwidth of the return loss of the receiver circuit 100 may be extended to a second frequency 280 before the return loss reaches and then exceeds the undesirable level 290.

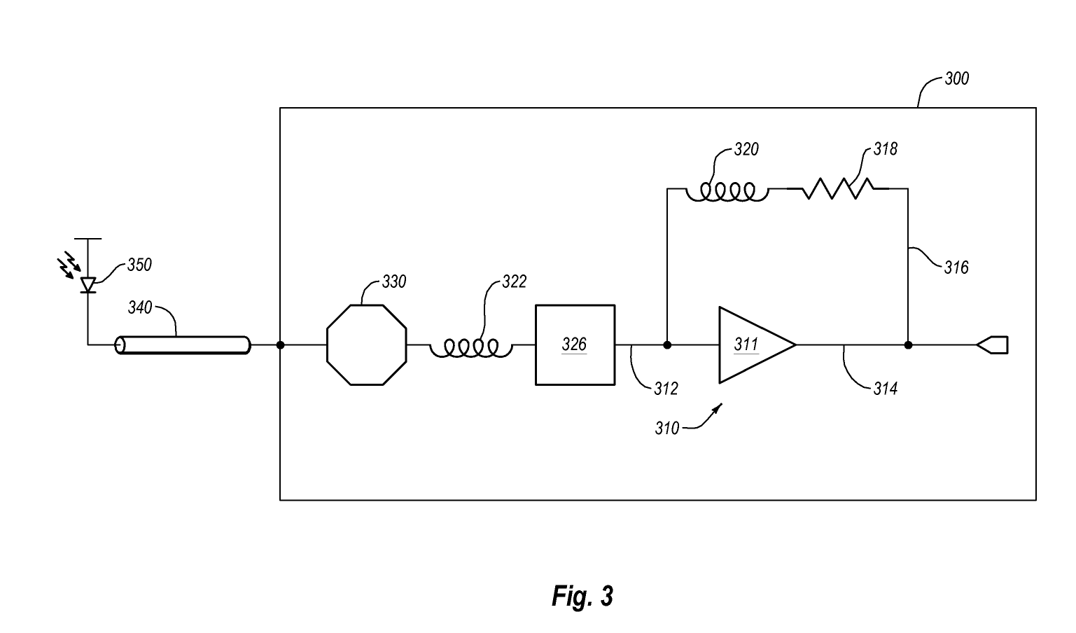

FIG. 3 is a circuit diagram of an optical receiver 300 that includes an example transimpedance amplifying circuit 310 with reduced signal loss, arranged in accordance with at least one embodiment described herein. The optical receiver 300 may include the transimpedance amplifying circuit 310, which includes a first inductor 320, a second inductor 322, a secondary circuit 326, and a pad 330.

The transimpedance amplifying circuit 310 may include an amplifier 311, an input node 312, an output node 314, and a feedback loop 316 that couples the input node 312 to the output node 314. The feedback loop 316 may include a resistance 318 and the first inductor 320. In particular, the resistance 318 may be coupled to the output node 314, the first inductor 320 may be coupled to the input node 312, and the first inductor 320 and the resistance 318 may be coupled together. The transimpedance amplifying circuit 310 may operate in a similar manner as the amplifying circuit 110 of FIG. 1. Accordingly, no further discussion of the transimpedance amplifying circuit 310 is provided with respect to FIG. 3.

The secondary circuit 326 may be coupled to the input node 312 of the transimpedance amplifying circuit 310. The secondary circuit 326 may be any circuit configured to provide additional functionality to the optical receiver 300. For example, in some embodiments, the secondary circuit 326 may be an electrostatic protection (ESP) circuit to protect the transimpedance amplifying circuit 310 from electrostatic or other errant voltages and/or currents discharged into the optical receiver 300.

The pad 330 may be configured to couple the optical receiver 300 to other circuits, traces, components, printed circuit boards (PCB), or similar items. For example, in some embodiments, solder, applied using a solder flow, may couple the pad 330, and thus the optical receiver 300, to a printed circuit board (PCB) or other device. In some embodiments, the pad 330 may be a conductive material, such as a metal.

The second inductor 322 may be coupled between the pad 330 and the secondary circuit 326. The second inductor 322 may be configured to help to reduce return loss of the optical receiver 300 over a broader bandwidth of frequencies. In some embodiments, the inductances of the second inductor 322 and the first inductor 320 may be related based on a gain of the transimpedance amplifying circuit 310. For example, in some embodiments, the inductance of the second inductor 322 may be approximately equal to the inductance of the first inductor 320 divided by the gain of the transimpedance amplifying circuit 310. Furthermore, in some embodiments, the first and second inductors 320 and 322 may be selected to have resonant frequencies that are higher than a highest frequency of a current signal received at the pad 330 of the optical receiver 300.

As illustrated, the pad 330 may be coupled to a trace 340. The trace 340 may be coupled to a photodiode 350. The photodiode 350 may be configured to generate a current signal based on received illumination. The current signal may pass through the trace 340 to the pad 330. The pad 330 may provide the current signal to the second inductor 322, which may pass the current signal to the transimpedance amplifying circuit 310 for conversion to a voltage signal as described herein.

In some embodiments, the trace 340 may have a particular impedance. For example, the trace 340 may have an impedance of 50, 60, 75, 90, or 100 ohms, or some other impedance. In these and other embodiments, an inductance of the second inductor 322 may be selected to offset the capacitance of the pad 330 to improve an input impedance bandwidth of the optical receiver 300. Alternately or additionally, the inductance of the second inductor 322 may be selected in relation to the capacitance and other characteristics of the pad 330 such that an input impedance of the optical receiver 300 is approximately equal to an impedance of the trace 340. By selecting the input impedance of the optical receiver 300 to be approximately equal to an impedance of the trace 340, return loss resulting from coupling the optical receiver 300 to the trace 340 may be reduced. Reducing the return loss may increase signal integrity and/or signal-to-noise ratio, among potentially other aspects of the current signal generated by the photodiode 350.

In FIG. 3, the optical receiver 300 may be constructed as an integrated circuit. In these and other embodiments, the transimpedance amplifying circuit 310, the second inductor 322, the secondary circuit 326, and the pad 330 may be formed as part of the optical receiver 300. As such, the transimpedance amplifying circuit 310, the second inductor 322, the secondary circuit 326, and the pad 330 may be formed on a single substrate together during the construction of the optical receiver 300.

Modifications, additions, or omissions may be made to the optical receiver 300 without departing from the scope of the present disclosure. For example, in some embodiments, another component other than a photodiode 350 may be configured to generate a current signal that is provided to the optical receiver 300 and thus the transimpedance amplifying circuit 310 by the trace 340.

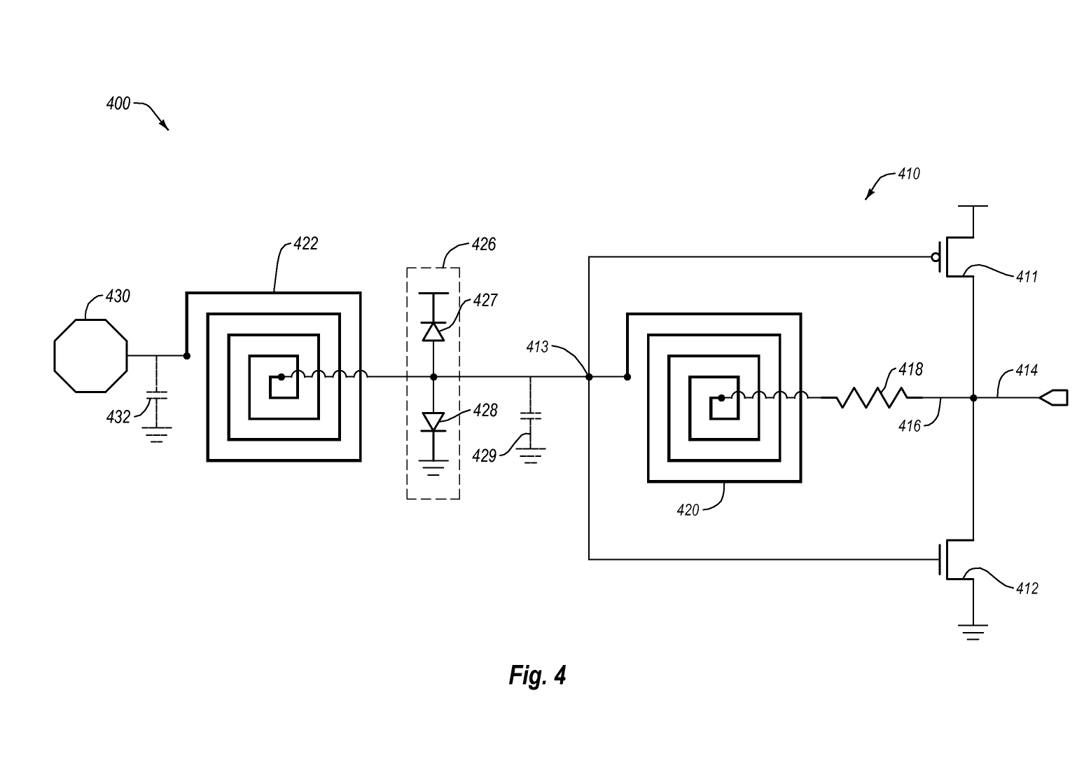

FIG. 4 is a circuit diagram of another example optical receiver 400 with an improved return loss, arranged in accordance with at least one embodiment described herein. The optical receiver 400 may include a transimpedance amplifying circuit 410, which includes a first inductor 420, an ESP circuit 426, a second inductor 422, and a pad 430.

The transimpedance amplifying circuit 410 may be configured as an inverting transimpedance amplifier. The transimpedance amplifying circuit 410 may include a first transistor 411, a second transistor 412, an input node 413, an output node 414, and a feedback loop 416 that couples the input node 413 to the output node 414. The feedback loop 416 may include a resistance 418, such as one or more resistors or other components that offer resistance, such as a body of a transistor, and the first inductor 420. The first inductor 420 may be coupled to the resistance 418 and the input node 413. The resistance 418 may be coupled to the output node 414 and the first inductor 420.

The first transistor 411 may be a p-channel metal-oxide-semiconductor field effect transistor (MOSFET) or some other type of p-channel type transistor. The second transistor 412 may be an n-channel MOSFET or some other type of n-channel type transistor. The gates of the first and second transistors 411 and 412 may be coupled to the input node 413. The sources of the first and second transistors 411 and 412 may be coupled to the output node 414. The drain of the first transistor 411 may be coupled to a voltage. The drain of the second transistor 412 may be coupled to ground.

The ESP circuit 426 may be coupled to the input node 413 and may include a first diode 427 and a second diode 428. The first diode 427 may be coupled between a voltage and the input node 413. The second diode 428 may be coupled between ground and the input node 413. The ESP circuit 426 and the input node 413 may have a parasitic capacitance 429.

The pad 430 may be configured to couple the optical receiver 400 to other circuits, traces, components, printed circuit boards (PCB), or similar items. In some embodiments, the pad 430 may be a conductive material, such as a metal. The pad 430 may have a parasitic capacitance 432.

The second inductor 422 may be coupled between the pad 430 and the input node 413. The second inductor 422 may be configured to help to reduce return loss of the optical receiver 400 over a broader bandwidth of frequencies. As illustrated in FIG. 4, the second inductor 422 may be positioned in a physical layout of the optical receiver 400 closer to the pad 430 than to the transimpedance amplifying circuit 410. For example, in the physical layout of the optical receiver 400, the second inductor 422 may be positioned such that the ESP circuit 426 is between the first inductor 420 and other components of the transimpedance amplifying circuit 410 and the second inductor 422. As a result of the position of the second inductor 422, the parasitic capacitance 432 is separated from the parasitic capacitance 429 by the second inductor 422. Positioning the second inductor 422 physically closer to the pad 430 may help to further extend the return loss bandwidth of the optical receiver 400 than if the second inductor 422 is positioned physically closer to the transimpedance amplifying circuit 410.

The inductance of each of the first and second inductors 420 and 422 may depend on the length of each of the first and second inductors 420 and 422, the position of the first and second inductors 420 and 422 with respect to each other, the configuration of each of the first and second inductors 420 and 422, and magnetic coupling between the first and second inductors 420 and 422 and other components in the optical receiver 400.

In some embodiments, the inductances of the second inductor 422 and the first inductor 420 may be related based on a gain of the transimpedance amplifying circuit 410. For example, in some embodiments, the inductance of the second inductor 422 may be approximately equal to the inductance of the first inductor 420 divided by the gain of transimpedance amplifying circuit 410. Furthermore, in some embodiments, the first and second inductors 420 and 422 may be selected to have resonant frequencies that are higher than a highest frequency of a current signal received at the pad 430 of the optical receiver 400.

Modifications, additions, or omissions may be made to the optical receiver 400 without departing from the scope of the present disclosure. For example, in some embodiments, the transimpedance amplifying circuit 410 may include more than the first and second transistors 411 and 412. For example, the transimpedance amplifying circuit 410 may include multiple other transistors coupled to the first and second transistors 411 and 412 to form a cascode transimpedance amplifying circuit 410. Alternately or additionally, the first and second inductors 420 and 422 may be formed to have a different shape than the square type looping shape illustrated in FIG. 4. For example, the shape of the first and second inductors 420 and 422 may be circular, hexagonal, pentagonal, rectangular, or triangular, among others. Alternately or additionally, the ESP circuit 426 may include additional or different components than the first and second diodes 427 and 428.

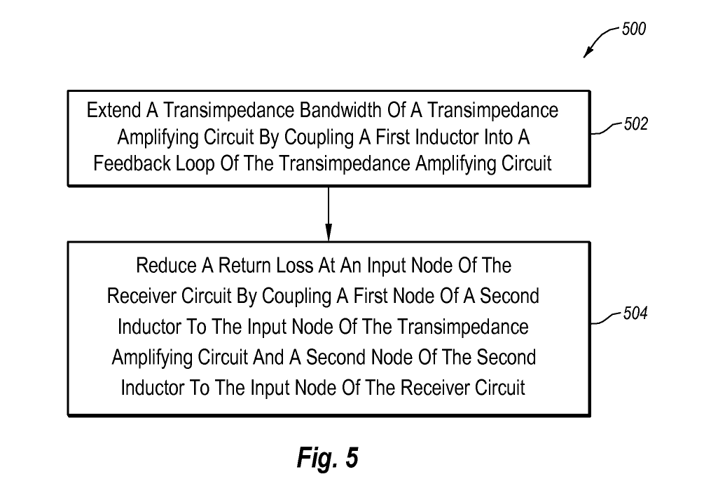

FIG. 5 is a flowchart of an example method 500 of reducing signal loss in a receiver circuit, arranged in accordance with at least one embodiment described herein. The method 500 may be implemented, in some embodiments, by a receiver circuit or optical receiver, such as the receiver circuit 100 of FIG. 1 or the optical receivers 300 or 400 of FIGS. 3 and 4, respectively. Although illustrated as discrete blocks, various blocks may be divided into additional blocks, combined into fewer blocks, or eliminated, depending on the desired implementation.

The method 500 may begin at block 502, where a transimpedance bandwidth of a transimpedance amplifying circuit may be extended by coupling a first inductor into a feedback loop of the transimpedance amplifying circuit.

In block 504, a return loss at an input node of the receiver circuit may be reduced by coupling a first node of a second inductor to the input node of the transimpedance amplifying circuit and a second node of the second inductor to the input node of the receiver circuit.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

For example, the method 500 may further include selecting an inductance of the second inductor to be approximately equal to an inductance of the first inductor divided by a gain of the transimpedance amplifying circuit. Alternately or additionally, the method 500 may include selecting an inductance of the second inductor such that an input impedance of the input node of the receiver circuit is approximately equal to an impedance of a trace coupled to the input node of the receiver circuit. Alternately or additionally, the method 500 may include selecting resonant frequencies of the first and second inductors to be higher than data frequency of a data signal provided to the transimpedance amplifying circuit.

All examples and conditional language recited herein are intended for pedagogical objects to aid the reader in understanding the invention and the concepts contributed by the inventor to furthering the art, and are to be construed as being without limitation to such specifically recited examples and conditions. Although embodiments of the present inventions have been described in detail, it should be understood that the various changes, substitutions, and alterations could be made hereto without departing from the spirit and scope of the invention.

What is claimed is:

1. A receiver circuit comprising:
an amplifying circuit including an input node, an output node, and a feedback loop coupled between the input node and the output node, the feedback loop including a first inductor, the amplifying circuit configured to receive a current signal on the input node and to output a voltage signal based on the current signal on the output node; and
a second inductor with a first node coupled to the input node of the amplifying circuit.

2. The circuit of claim 1, wherein the feedback loop further includes a resistance.

3. The circuit of claim 1, wherein the amplifying circuit amplifies the current signal by a gain.

4. The circuit of claim 3, wherein an inductance of the second inductor is approximately equal to an inductance of the first inductor divided by the gain of the amplifying circuit.

5. The circuit of claim 1, wherein the current signal represents a data signal with a data frequency, wherein resonant frequencies of the first and second inductors are higher than the data frequency.

6. The circuit of claim 1, wherein an inductance of the first inductor is configured to affect a bandwidth of the amplifying circuit and an inductance of the second inductor is configured to affect a return loss at an input of the receiver circuit.

7. The circuit of claim 1, wherein the amplifying circuit and the second inductor are formed in an integrated circuit.

8. The circuit of claim 7, wherein the integrated circuit includes a pad for coupling the integrated circuit to a trace, wherein a second node of the second inductor is coupled to the pad and an inductance of the second inductor is selected such that an input impedance of the integrated circuit is approximately equal to an impedance of the trace.

9. The circuit of claim 1, further comprising a secondary circuit coupled to the input node of the amplifying circuit.

10. The circuit of claim 9, wherein the secondary circuit includes an electrostatic protection circuit.

11. An optical receiver comprising:
a pad coupled to a trace, the pad configured to receive a current signal from the trace;
a transimpedance amplifying circuit including an input node, an output node, and a feedback loop coupled between the input node and the output node, the feedback loop including a first inductor, the transimpedance amplifying circuit configured to receiver the current signal, convert the current signal to a voltage signal, and to amplify the current signal by a gain; and
a second inductor coupled between the pad and the input node of the transimpedance amplifying circuit.

12. The optical receiver of claim 11, wherein an inductance of the second inductor is approximately equal to an inductance of the first inductor divided by the gain of the transimpedance amplifying circuit.

13. The optical receiver of claim 11, further comprising an electrostatic protection circuit coupled to the input node of the transimpedance amplifying circuit.

14. The optical receiver of claim 11, wherein the current signal represents a data signal with a data frequency, wherein resonant frequencies of the first and second inductors are higher than the data frequency.

15. The optical receiver of claim 11, wherein an inductance of the second inductor is selected such that an input impedance of the optical receiver is approximately equal to an impedance of the trace.

16. The optical receiver of claim 11, wherein resonant frequencies of the first and second inductors are higher than a data frequency of the current signal.

17. A method of reducing return loss in a receiver circuit, the method comprising:
extending a transimpedance bandwidth of a transimpedance amplifying circuit by coupling a first inductor into a feedback loop of the transimpedance amplifying circuit; and
reducing a return loss at an input node of the receiver circuit by coupling a first node of a second inductor to the input node of the transimpedance amplifying circuit and a second node of the second inductor to the input node of the receiver circuit.

18. The method of claim 17, further comprising selecting an inductance of the second inductor to be approximately equal to an inductance of the first inductor divided by a gain of the transimpedance amplifying circuit.

19. The method of claim 17, further comprising selecting an inductance of the second inductor such that an input impedance of the input node of the receiver circuit is approximately equal to an impedance of a trace coupled to the input node of the receiver circuit.

20. The method of claim 17, further comprising selecting resonant frequencies of the first and second inductors to be higher than a data frequency of a data signal provided to the transimpedance amplifying circuit.
